(19) United States
(12) Patent Application Publication
(10) Pub. No.: US 2004/0051177 A1
(43) Pub. Date: Mar. 18, 2004

(54) Adaptation of an integrated circuit to specific needs

(76) Inventor: Jean-Pierre Schoellkopf, Grenolle (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/614,686

(22) Filed: Jul. 7, 2003

(30) Foreign Application Priority Data
Jul. 12, 2002 (FR) 02/08860

(51) Int. Cl. H01L 23/48

(52) U.S. Cl. 257/758

(57) ABSTRACT

A method for adapting to specific needs an integrated circuit having a stack of insulating layers, each layer being associated with a determined metallization level, metal areas of the last metallization level forming electric contacts of the integrated circuit, including the steps of forming pairs of metal regions of the penultimate metallization level having a facing edge and connected to components of the integrated circuit; depositing an insulating layer; etching according to the specific needs the insulating layer to expose the facing edges of the metal regions of determined pairs; and forming metal portions of the last metallization level which cover the facing edges of the metal regions of all pairs and which contact the metal regions of the determined pairs.

### BACKGROUND OF THE INVENTION

1. Field of the Invention

The present invention relates to a method for adapting an integrated circuit to specific needs. The present invention also relates to the structure obtained by said method.

2. Discussion of the Related Art

Upon manufacturing of an integrated circuit, frequently adaptations of the integrated circuit have to be made according to specific needs formulated by the future user of the integrated circuit. For example, the user may desire to code in the integrated circuit specific data bits. Such data may correspond to identification numbers of the product on which the integrated circuit is intended to operate, of the wafer batch to which the integrated circuit belongs, of the wafer in the wafer batch on which the integrated circuit has been made, of the nature of the integrated circuit, etc. The data may also correspond to a code formed of several bits which will be used subsequently by the user, for example, to implement encryption operations. The integrated circuit adaptation may also consist of providing specific correction means to possibly correct some data stored in memories formed in the integrated circuit which would appear to be defective upon tests.

It is preferable for the adaptation operations to be performed at the last steps of the integrated circuit manufacturing method. Indeed, this avoids modifying most of the manufacturing process steps, which remain common to all integrated circuits in the same wafer, whatever their subsequent destination. Further, it is preferable for the integrated circuit adaptation steps to implement as much as possible usual technologies of semiconductor manufacturing processes and to have a low cost as compared to the general integrated circuit manufacturing cost.

An integrated circuit adaptation is generally performed as follows. Fuses formed of metal tracks are formed at the level of the last integrated circuit metallization levels. At the last steps of the integrated circuit manufacturing process, and according to the user's needs, some of the tracks are opened by means of a laser beam. A terminal of the fuse may be intended, upon subsequent operation of the integrated circuit, to be connected to ground and the other terminal may be intended to be connected to a high voltage. The open fuses then enable, for example, coding of an information corresponding to a bit “1”, and the fuses maintained intact enable coding an information corresponding to a bit “0”. The fuse may also be connected to a memory, for example, a random access static or dynamic integrated memory (ESRAM or EDRAM). The fuse opening can then enable correcting the data to be stored in the memory if it appears to be defective upon tests performed at the last steps of the integrated circuit manufacturing process.

Such an integrated circuit adaptation method has disadvantages. Indeed, the use of a laser beam requires specific precautions. More specifically, each metal track corresponding to a fuse must generally have a length of at least 10 micrometers and be distant from other metal tracks by at least 50 micrometers for the track opening by the laser beam to avoid damaging the neighboring tracks. The surface density of the metal tracks is thus limited and the surface area necessary for the data coding may thus be significant, all the more as the currently-coded data may comprise more than 100 bits. Since the minimum required surface area is linked to the laser technology, it cannot be decreased whatever the semiconductor manufacturing processes used.

Further, no deposition, for example, of a thick passivation layer, is generally performed on the integrated circuit once the fuse opening operation has been performed. This means that an observation of the integrated circuit surface enables distinguishing what fuses have been opened by laser beam. The identification of the information coded on the integrated circuit may be thereby eased, which may not be desirable.

### SUMMARY OF THE INVENTION

The present invention aims at providing a method for adapting an integrated circuit to specific needs implemented at the last steps of the integrated circuit manufacturing process, having a low implementation cost and requiring an integrated circuit surface area smaller than that used by conventional methods.

The present invention also aims at obtaining an integrated circuit adaptation method for which the obtained structure provides no visual indication as to the nature of the performed adaptation.

To achieve these and other objects, the present invention provides a method for adapting to specific needs an integrated circuit comprising a stack of insulating layers, each layer being associated with a determined metallization level, metal areas of the last metallization level forming electric contacts of the integrated circuit, comprising the steps of: (a) forming pairs of metal regions of the penultimate metallization level having a facing edge and connected to components of the integrated circuit; (b) depositing an insulating layer; (c) etching according to the specific needs the insulating layer to expose the facing edges of the metal regions of determined pairs; and (d) forming metal portions of the last metallization level which cover the facing edges of the metal regions of all pairs and which contact the metal regions of the determined pairs.

According to an embodiment of the present invention, step (d) comprises depositing a metal layer of the last metallization level, and of delimiting in the metal layer the metal portions.

According to an embodiment of the present invention, the metal areas are delimited in the metal layer simultaneously with the metal portions.

According to an embodiment of the present invention, the method further comprises the steps of depositing a passivation layer; and etching openings exposing the metal areas.

According to an embodiment of the present invention, the etching of the insulating layer is a direct etching by an electron beam.

According to an embodiment of the present invention, the metal portions are metal connection balls.

The present invention also relates to an integrated circuit adapted to specific needs, comprising a stack of insulating layers, each layer being associated with a determined metallization level, metal areas of the last metallization level forming electric contacts of the integrated circuit, comprising pairs of metal regions of the penultimate metallization level having a facing edge and connected to components of the integrated circuit; insulating portions covering the edges of the metal regions of determined pairs according to the specific needs; and metal portions of the last metallization level which cover the facing edges of the metal regions of all pairs and which connect the metal regions of the pairs other than the determined pairs.

According to an embodiment of the present invention, the circuit further comprises a passivation layer covering the metal portions.

The foregoing objects, features, and advantages of the present invention, will be discussed in detail in the following non-limiting description of specific embodiments in connection with the accompanying drawings.

### BRIEF DESCRIPTION OF THE DRAWINGS

FIGS. 1A to 1E show cross-sections of a portion of an integrated circuit at successive steps of a first embodiment of the adaptation method according to the present invention; and

FIG. 2 shows a cross-section of an integrated circuit obtained by a second embodiment of the method according to the present invention.

### DETAILED DESCRIPTION

Two embodiments of the method according to the present invention will be described in detail. It should be noted that in the different drawings, as usual in the field of integrated circuit representation, the thicknesses and lateral dimensions of the various layers are not drawn to scale, neither within a same drawing, nor from one drawing to the other, to improve the readability of this drawing. Further, the same reference numerals will refer to the same elements in the different drawings.

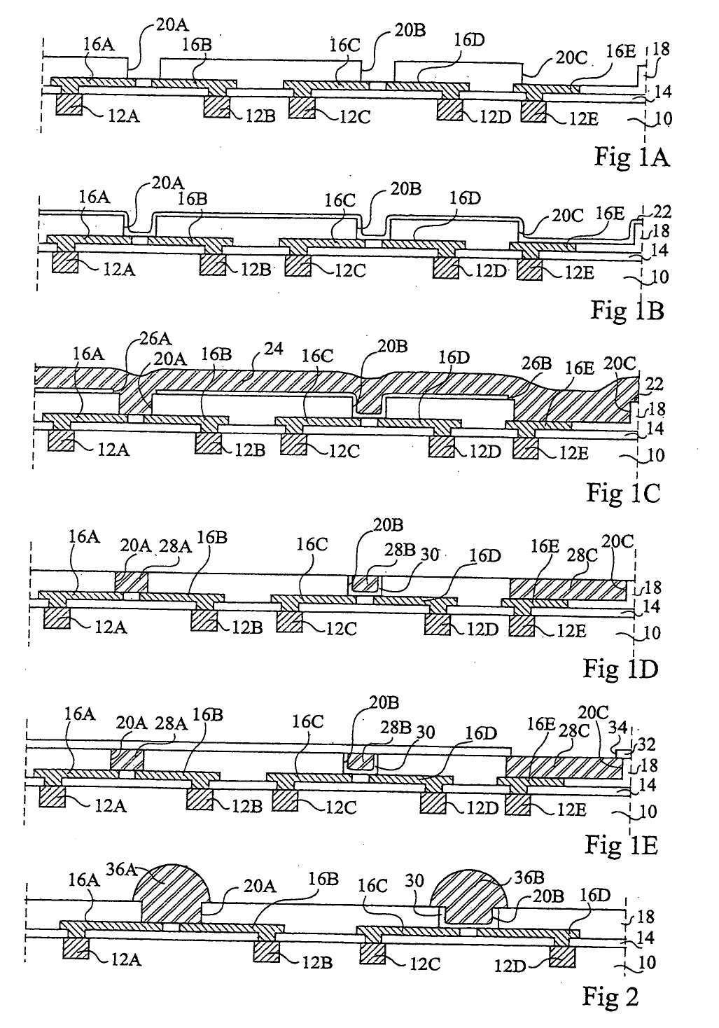

FIG. 1A shows a cross-section of a portion of an integrated circuit at the level of the last metallization levels. The integrated circuit comprises an insulating layer 10, for example, silicon oxide, comprising metal portions 12A to 12E, for example copper or aluminum, belonging to the antepenultimate metallization level. Metal portions 12A to 12E for example correspond to tracks or to vias connected to components not shown formed in the integrated circuit. An insulating intermetallic layer 14, for example, silicon oxide, covers insulating layer 10. Metal regions 16A to 16E, belonging to the penultimate metallization level, and formed for example of copper or aluminum, extend over intermetallic layer 14. Metal regions 16A to 16E are respectively connected to metal portions 12A to 12E through intermetallic layer 14. Metal regions 16A to 16E are distributed in a metal region 16E and in two pairs of metal regions 16A, 16B, and 16C, 16D, two metal regions of a same pair having a facing edge. The integrated circuit comprises several other pairs of metal regions, not shown, similar to metal region pairs 16A to 16D, as well as other metal regions, not shown, similar to metal region 16E. Each pair of metal regions 16A to 16D forms an “anti-fuse”, that is, a component that, in the “unmodified” state, is equivalent to an open switch, and that, in the “modified” state, is equivalent to a closed switch.

A dielectric layer 18, for example, silicon nitride, covers metal regions 16A to 16E and intermetallic layer 14. Openings 20A, 20B, 20C formed in dielectric layer 18 expose a portion of metal region 16E and the facing edges of metal regions 16A to 16D of the metal pairs.

FIG. 11B shows the structure obtained after deposition of a thin insulating layer 22 on dielectric layer 18, formed for example by a conformal deposition of silicon oxide.

FIG. 1C shows the structure obtained after etching of recesses 26A, 26B in thin layer 22 and deposition of a metal layer 24, for example, copper or aluminum, over the entire integrated circuit. Preferably, thin layer 22 is directly etched by an electron beam. Recesses 26A, 26B are etched in thin layer 22, at the level of openings 20A and 20C of dielectric layer 18, to expose the facing edges of metal regions 16A, 16B and metal region 16E. Metal layer 24 is thus electrically connected to metal regions 16A, 16B, 16E and not to regions 16C and 16D.

FIG. 1D shows the structure obtained after performing a planarization step, for example, by chem-mech polishing ensuring an etch of metal layer 24 and of thin layer 22 down to the surface of dielectric layer 18. Metal portions 28A, 28B, 28C are thus delimited in openings 20A to 20C of dielectric layer 18. In openings 20A, 20C where thin layer 22 has been etched, metal portions 28A, 28C are in contact with metal regions 16A, 16B, 16E. In opening 20B where thin layer 22 has not been etched, metal portion 28B is separated from metal regions 16C, 16D by an insulating portion 30.

FIG. 1E shows the structure obtained after deposition of a passivation layer 32 and the etching in passivation layer 32 of an opening 34 exposing metal portion 28C. Metal portion 28C forms a contact pad. Connection wires may be welded to this pad.

Metal portion 28A performs an electric connection between metal regions 16A, 16B and thus closes the corresponding “anti-fuse”. As an example, in the case where metal portion 16A is grounded and metal portion 16B is connected to a high voltage via a resistor, the coded information corresponds to a bit “0”.

Similarly, metal regions 16C, 16D remain insulated from each other and thus form an open anti-fuse. In the case where one of the metal regions is grounded and the other one is connected to a high voltage, the coded information corresponds to a bit “1”.

The present invention thus comprises forming anti-fuses formed of pairs of metal regions in the penultimate metallization level, having facing edges, and which are maintained open or which are closed at the last steps of the integrated circuit manufacturing process according to the circuits user's specific needs. As appears in FIGS. 1A to 1E, the method according to the present invention enables forming and selective closing of the anti-fuses in parallel with the forming of the integrated circuit contacts.

FIG. 2 shows a cross-section view of an integrated circuit obtained according to a second embodiment of the present invention, only two anti-fuses being shown. In the second embodiment, after steps similar to those shown in FIGS. 1A and 1B, thin layer 22 is etched at the level of opening 20A, and contact balls 36A, 36B, for example, tin-lead based, are formed in all openings. Balls 36A, 36B are intended for the direct attaching of the integrated circuit on an external substrate according to the so-called “flip-chip” technology. Ball 36A ensures the connection between metal regions 16A and 16B, the corresponding anti-fuse being thus closed. Ball 36B is separated from metal regions 16C and 16D by an insulating portion 30, the corresponding anti-fuse thus remaining open.

Balls 36A, 36B are intended to only form the mechanical connection between the integrated circuit and the substrate on which the integrated circuit is to be attached, but are not intended to be electrically connected to the external substrate on which the integrated circuit is attached. Connection balls (not shown) connected to regions corresponding to region 16E of FIG. 1 ensure the electric and mechanical connection between the integrated circuit and the external substrate.

The present invention has many advantages.

First, it enables easy adaptation of an integrated circuit to specific needs by the closing of anti-fuses formed in the integrated circuit, the anti-fuse closing step being carried out at the last steps of the integrated circuit manufacturing process.

Second, in the first embodiment according to the present invention, the surface density of the anti-fuses can be high since the methods implemented for their forming and their possible closing are conventional semiconductor manufacturing processes. In the second embodiment of the present invention, the surface density of the anti-fuses is limited to the surface density which can be obtained for the connection balls.

Third, the etching of the thin insulating layer may be performed directly by a computer-driven electron beam. An electron beam etch is typically slower than an etching implementing a mask. Indeed, the electron beam successively etches the different areas of the insulating layer corresponding to the anti-fuses to be closed. However, given the relatively small number of areas to be etched, this is not prejudicial. Further, the use of a programmable electron beam is less expensive than an etching requiring forming of a mask.

Fourth, the structure obtained by the present method does not enable detecting by simple visual observation whether the anti-fuses are open or closed.

Fifth, in the first embodiment, the forming of the anti-fuses is compatible with the forming of the integrated circuit contact pads, and in the second embodiment with the forming of the connection balls.

Of course, the present invention is likely to have various alterations, modifications, and improvements which will readily occur to those skilled in the art. In particular, the different insulating layers and the different metal portions may be formed of any adapted material.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for adapting to specific needs an integrated circuit comprising a stack of insulating layers, each layer being associated with a determined metallization level, metal areas of the last metallization level forming electric contacts of the integrated circuit, comprising the steps of:
(a) forming pairs of metal regions of the penultimate metallization level having a facing edge and connected to components of the integrated circuit;
(b) depositing an insulating layer;
(c) etching according to the specific needs the insulating layer to expose the facing edges of the metal regions of determined pairs; and
(d) forming metal portions of the last metallization level which cover the facing edges of the metal regions of all pairs and which contact the metal regions of the determined pairs.

2. The method of claim 1, wherein step (d) comprises depositing a metal layer of the last metallization level, and delimiting in the metal layer said metal portions.

3. The method of claim 2, wherein the metal areas are delimited in the metal layer simultaneously with the metal portions.

4. The method of claim 3, further comprising:
depositing a passivation layer; and
etching openings exposing the metal areas.

5. The method of claim 1, wherein the etching of the insulating layer is a direct etching by an electron beam.

6. The method of claim 1, wherein the metal portions are metal connection balls.

7. An integrated circuit adapted to specific needs, comprising a stack of insulating layers, each layer being associated with a determined metallization level, metal areas of the last metallization level forming electric contacts of the integrated circuit, comprising:
pairs of metal regions of the penultimate metallization level having a facing edge and connected to components of the integrated circuit;
insulating portions covering the edges of the metal regions of determined pairs according to the specific needs; and
metal portions of the last metallization level which cover the facing edges of the metal regions of all pairs and which connect the metal regions of the pairs other than the determined pairs.

8. The integrated circuit of claim 7, further comprising a passivation layer covering the metal portions.
